(19) United States
(12) Patent Application Publication
(10) Pub. No.: US 2015/0138863 A1
(43) Pub. Date: May 21, 2015

(54) INTERLEAVED WRITE ASSIST FOR HIERARCHICAL BITLINE SRAM ARCHITECTURES

(71) Applicant: LSI CORPORATION, San Jose, CA (US)

(72) Inventors: Rajiv Kumar Roy, Bangalore (IN); Donald Albert Evans, Carroll, OH (US); Rasoju Veerabadra Chary, Bangalore (IN); Rahul Sahu, Bangalore (IN)

(73) Assignee: LSI CORPORATION, San Jose, CA (US)

(21) Appl. No.: 14/086,171

(22) Filed: Nov. 21, 2013

Related U.S. Application Data
(60) Provisional application No. 61/904,746, filed on Nov. 15, 2013.

(51) Int. Cl. G11C 11/419

(52) U.S. Cl. CPC G11C 11/419
USPC 365/72

(57) ABSTRACT

An SRAM device includes a plurality of memory cells and a first metallization layer comprising a first pair of bitlines operable to couple to a first segment of the memory cells. The device also includes a second metallization layer comprising a second pair of bitlines operable to couple to a second segment of the memory cells and a write assist line interleaved with the first and second metallization layers to provide a substantially constant coupling capacitance with each of the first and second pairs of bitlines.

### CROSS REFERENCE TO RELATED APPLICATIONS

This patent application is a non-provisional patent application claiming priority to and thus the benefit of an earlier filing date from U.S. Provisional Patent Application No. 61/904,746 (filed Nov. 15, 2013), the contents of which are hereby incorporated by reference.

### FIELD OF THE INVENTION

The invention generally relates to field of Synchronous Random Access Memories (SRAM) employing write assist and hierarchical bitlines.

### BACKGROUND

Submicron SRAM can experience write failures under certain operational conditions. To assist in this regard, “write assist” lines have been developed that pull bitlines below ground to ensure that logical zeros are written in memory cells. However, certain gates can be overdriven by larger magnitude negative voltages being variably applied to the gates. These variable voltages are due in part to variable coupling capacitances between bitlines and write assist lines in a memory cell array. This can at least lead to improperly written data and possibly to the more disastrous consequences of damaging the transistors in the array.

### SUMMARY

SRAM devices herein improve write operations and transistor gate reliability by employing various configurations of write assist lines. In these configurations, the write assist lines are spaced in the metallization layers of a device a certain distance from bitlines so as to provide a substantially constant coupling capacitance throughout a memory cell array of the device. In one embodiment, an SRAM device includes a plurality of memory cells and a first metallization layer comprising a first pair of bitlines operable to couple to a first segment of the memory cells. The device also includes a second metallization layer comprising a second pair of bitlines operable to couple to a second segment of the memory cells and a write assist line interleaved with the first and second metallization layers to provide a substantially constant coupling capacitance with each of the first and second pairs of bitlines.

The various embodiments disclosed herein may be implemented in a variety of ways as a matter of design choice. For example, some embodiments herein are implemented in hardware whereas other embodiments may include processes that are operable to construct and/or operate the hardware. Other exemplary embodiments are described below.

### BRIEF DESCRIPTION OF THE FIGURES

Some embodiments of the present invention are now described, by way of example only, and with reference to the accompanying drawings. The same reference number represents the same element or the same type of element on all drawings.

FIG. 1 is a block diagram of an exemplary SRAM device employing an interleaved write assist.

FIG. 2 is a block diagram of the segmented memory cell array of FIG. 3 illustrating global and local bitline couplings in the memory cell segments.

FIG. 3 is a block diagram of a segmented memory cell array of an SRAM device employing interleaved write assist.

FIG. 4 is a block diagram of another segmented memory cell array of an SRAM device employing interleaved write assist.

### DETAILED DESCRIPTION OF THE FIGURES

The figures and the following description illustrate specific exemplary embodiments of the invention. It will thus be appreciated that those skilled in the art will be able to devise various arrangements that, although not explicitly described or shown herein, embody the principles of the invention and are included within the scope of the invention. Furthermore, any examples described herein are intended to aid in understanding the principles of the invention and are to be construed as being without limitation to such specifically recited examples and conditions. As a result, the invention is not limited to the specific embodiments or examples described below.

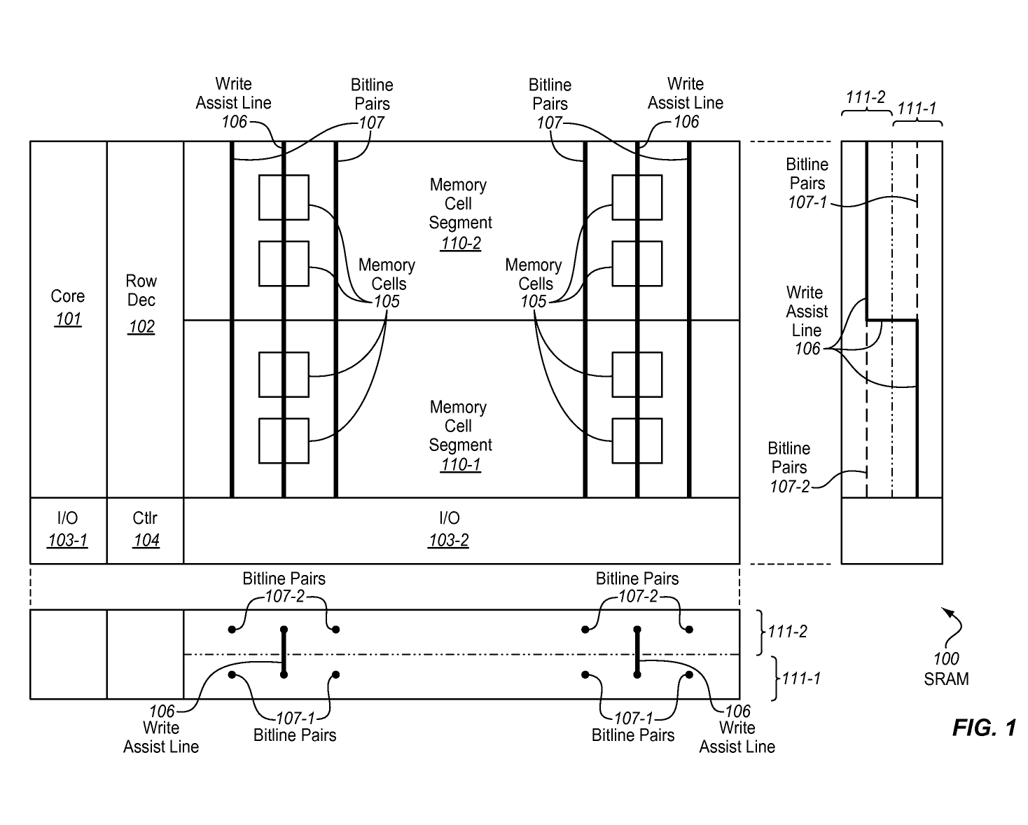

FIG. 1 is a block diagram of an exemplary SRAM device 100 employing write assist. FIG. 1 illustrates three views of the SRAM device 100 (i.e., an overhead view and two side views) to illustrate bitline and write assist line configurations within multiple metallization layers 111-1 and 111-2 in the SRAM device 100.

In this embodiment, the SRAM device 100 is configured with modules that are operable to perform I/O operations to memory cells 105 of a memory cell array 110. These modules include, but are not limited to, an SRAM core 101, a row decoder 102, I/O modules 103-1 and 103-2, and an I/O controller 104. The I/O modules 103-1 and 103-2 in combination with the I/O controller 104 provide a global I/O to the memory cells 105 in the memory cell array 110.

The memory cell array 110 is segmented with each memory cell segment 110-1 and 110-2 comprising columns of memory cells 105. The memory cells 105 of the memory cell segment 110 are configured in a first metallization layer 111-1 (a.k.a., a lower metallization layer or substrate layer of a semiconductor device). Running through each of the memory segments 110-1 and 110-2 in column-wise fashion are pairs of bitlines 107-1 and 107-2 that couple to the memory cells 105 to write data to the memory cells 105 based on signals from the global I/O.

The bitline pairs 107-1 are configured in the first metallization layer 111-1 and the bitline pairs 107-2 are configured in a second metallization layer 111-2 (a.k.a., an upper metallization layer). The bitline pairs 107-1 and 107-2 couple to the memory cells 105 according to memory cell segment 110-1 and 110-2. To illustrate, the bitline pairs 107-2 in the second metallization layer 111-2 couple to the memory cells 105 in the memory cell segment 110-2 whereas the bitline pairs 107-1 in the first metallization layer 111-1 couple to the memory cells 105 in the memory cell segment 110-1. The bitline pairs 107-1 and 107-2 are global bitlines that couple to local bitlines in the memory cell segments.

This segmented coupling of bitline pairs 107 generally means that the bitline pairs 107-2 do not couple to the memory cells 105 in the memory cell segment 110-1 and the bitline pairs 107-1 do not couple to the memory cells 105 in the memory cell segment 110-2. As shown in the lower side view in FIG. 1, the bitline pairs 107-2 in the second metallization layer 111-2 run parallel to and, in general, directly on top of the bitline pairs 107-1 in the first metallization layer 111-1.

To assist in writing bits to the memory cells 105, the memory cell array 110 is also configured with write assist lines 106 that are operable to boost the negative voltage on the bitline pairs 107 during write operations. The write assist lines 106, in this embodiment, run parallel to the bitline pairs 107 throughout the memory cell segments 110-1 and 110-2. Differing from how the bitline pairs 107 traverse the memory cell segments 110-1 and 110-2 is the manner in which the write assist lines 106 traverse through the different metallization layers 111-1 and 111-2. For example, a write assist line 106 may couple to the global I/O module at the lower metallization layer 111-1 and traverse the memory cell segment 110-1 alongside a bitline pair 107-1. Where the write assist line 106 approaches the memory cell segment 110-2, the write assist line 106 transitions from the lower metallization layer 111-1 to the upper metallization layer 111-2 in continuous fashion to interleave through the metallization layers 111. From there, the write assist line 106 traverses the memory cell segment 110-2 alongside a bitline pair 107-2.

As can be seen in the cross-sectional view in the lower part of FIG. 1, the bitline pairs 107-1 and 107-2 are, in general, directly on top of each other throughout the memory cell in segments 110-1 and 110-2, respectively. And, while the write assist line 106 traverses the metallization layers 111 at the boundary of the memory cell segments 110-1 and 110-2, it maintains a relatively equal distance from the bitline pairs 107-1 and 107-2 in each of the memory cell segments 110-1 and 110-2. In other words, the distance between the write assist line 106 in the memory cell segment 110-1 and each of the bitlines in the bitline pair 107-1 is generally the same as the distance between the write assist line 106 in the memory cell segment 110-2 and each of the bitlines in the bitline pair 107-2.

The relatively constant distances between the interleaved write assist lines 106 and the bitline pairs 107-1 and 107-2 and the occurrence of coupling capacitance only when the bitline pairs 107-1 and 107-2 are connected to memory cells 105 provides a substantially constant coupling capacitance through each memory cell segment 110. This substantially constant coupling capacitance helps to assure that the transistors (not shown) in each of the memory cells 105 are not overdriven during write operations. For example, a write assist signal applied to the write assist line 106 during a write operation is operable to boost the negative voltage on the bitlines of the bitline pairs 107-1 and 107-2. The negative boost voltage (V_{boost}) is generally a function of the coupling capacitance (c_{coupling}) between the write assist lines 106 and the bitlines of the bitline pairs 107-1 and 107-2, the total capacitance (Cₜₒₜₐₗ) of each of the bitlines, and the negative supply voltage (V_{dd}) for the write assist signal. More specifically, V_{boost}=V_{dd} (C_{coupling}/Cₜₒₜₐₗ). By maintaining a stable coupling capacitance C_{coupling}, the negative boost voltage V_{boost} is controlled, which in turn provides a more stable bitline signal being applied to the transistors in the memory cells 105. This helps to ensure that data is correctly written to the memory cells 105 and helps to prevent the transistors in the memory cells 105 from being overdriven.

Although shown and described with respect to having to memory cell segments 110-1 and 110-2, the invention is not intended to be so limited. Rather, the memory cell array 110 may include multiple memory cell segments. For example, in one embodiment, there may be two metallization layers above a local bitline layer and the memory cell array 110 may be further segmented. Additionally, the invention is not intended to be limited to any number of columns of bitline pairs 107. Generally, each segment of the memory cell array 110 is configured with many columns of bitline pairs 107 (e.g., millions of columns). The embodiments of this disclosure are merely shown in exaggerated form to assist the reader in understanding the fundamentals of the inventive concepts herein.

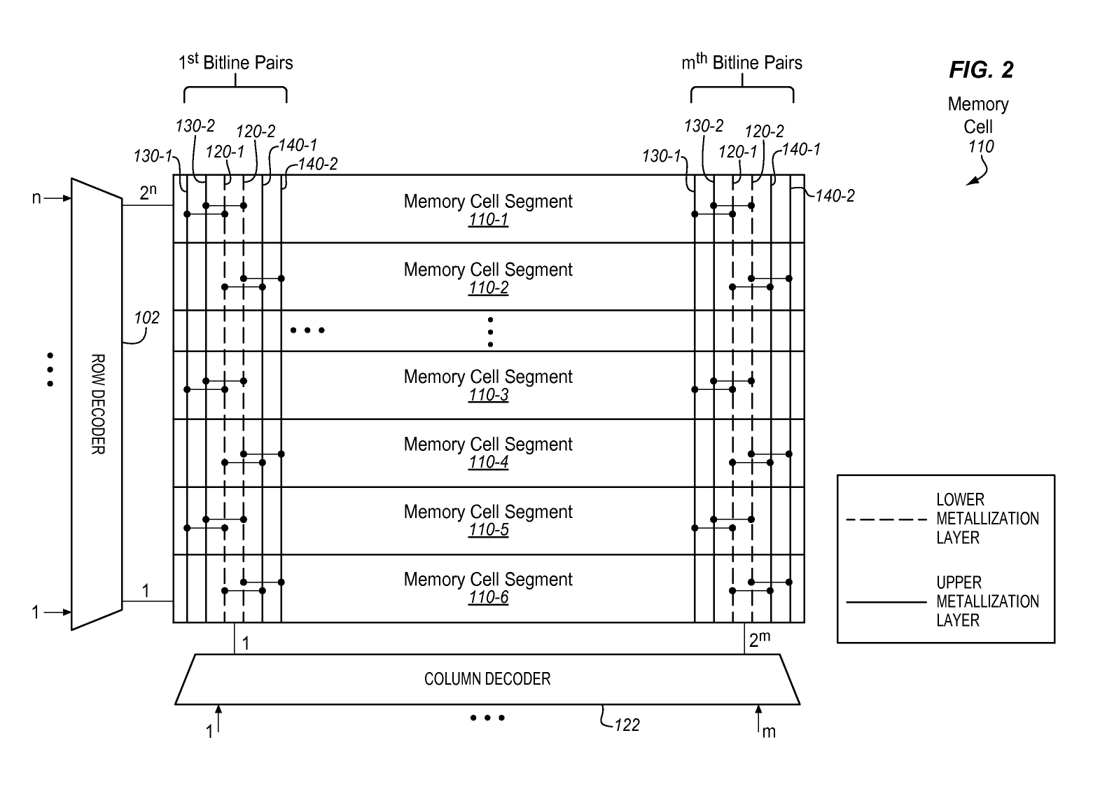

Additional examples of interleaved write assist and memory cells with multiple memory cell segments are shown and described in the embodiments below in FIGS. 2-4.

FIG. 2 is a block diagram of the architecture of the memory cell array 110 illustrating alternating memory cell segments 110-1-110-6. The write assist lines 106 are not shown in this illustration to improve clarity and understanding of the bitline couplings to the memory cells 105. Each segment of the memory cell array 110 is associated with a local bitline 120 that is specific to that segment. The local bitline 120 runs in lower metallization, as indicated by the dashed line in FIG. 2. As is understood in the art, a local bitline 120 can comprise a pair—which may be referred to herein as a true local bitline 120-1 and a complementary local bitline 120-2. Thus, the true local bitline 120-1 and the complementary local bitline 120-2 run in lower metallization and connect to each memory cell in one segment of the memory cell array 110. It should be noted that the true local bitline 120-1 and the complementary local bitline 120-2 are referred to collectively here for the sake of simplicity and that the terminology is not meant to denote a specific number of bitlines. For instance, for a given column of the memory cell array 110, there is a separate local bitline 120 in each segment 110 instead of just a single local bitline that extends throughout multiple segments (e.g., segments 110-1-110-6).

In the upper metallization layer, there are two pairs of global bitlines—an even global bitline pair 140 and an odd global bitline pair 130. Thus, each column in the memory cell array 100 has a plurality of bitline pairs—two pairs of global bitlines in upper metallization (e.g., 130-1, 130-2, 140-1, and 140-2) running across (or above) a range of segments 110, and a pair of local bitlines in lower metallization specific to each segment 110 (e.g., 120-1 and 120-2).

The local bitline 120 connects to either the even global bitline 140 or the odd global bitline 130 depending on the segment 110 in which the local bitline 120 is located. A global I/O toggles one of the two global bitline pairs 130/140 (i.e., even or odd global bitline) depending on the segment that is being selected (i.e., even or odd segment). To illustrate, in segment 110-2 (i.e., an even segment), the local bitline 120 connects to the even global bitline 140. In segment 110-3 (i.e., an odd segment), the local bitline 120 connects to the odd global bitline 130. In order to perform a read or write operation on, for example, a memory cell in the even segment (e.g., 110-2), a global I/O toggles the even global bitline (i.e., 140) in the column m of that memory cell. Put another way, the true and complement of a local bitline (i.e., 120-1, 120-2) in an even segment (e.g., 110-2, 110-4) connect to the true and complement, respectively, of the even global bitline (i.e., 140-1, 140-2). And, the true and complement of a local bitline (i.e., 120-1, 120-2) in an odd segment (e.g., 110-1, 110-3) connect to the true and complement, respectively, of the odd global bitline (i.e., 130-1, 130-2). This structure may be repeated for each of the m columns of the memory cell array 100.

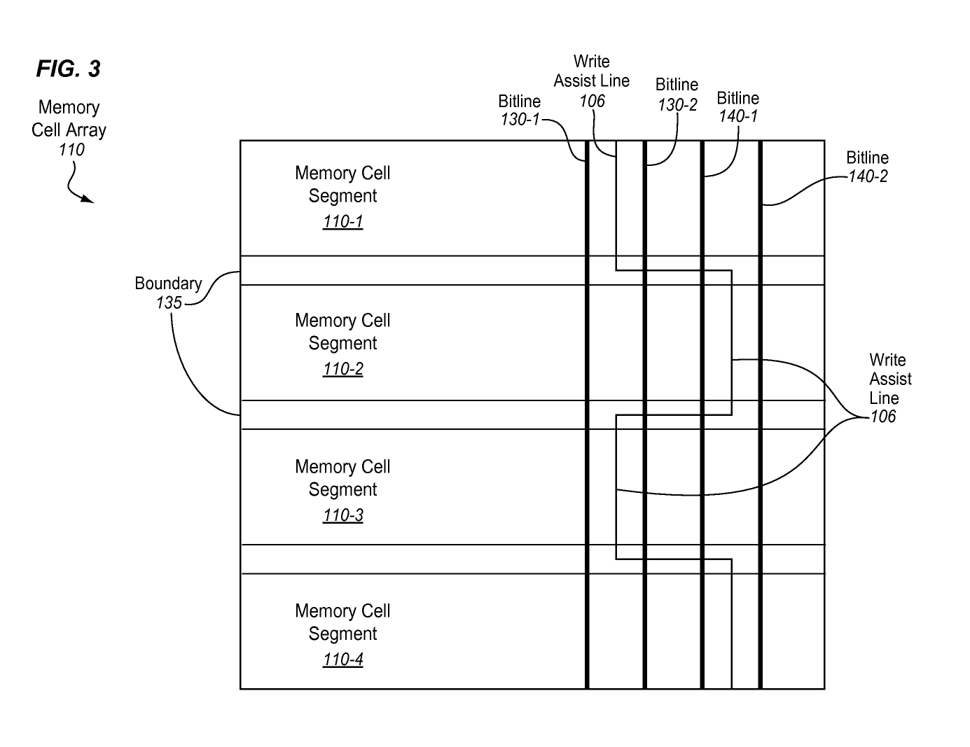

FIG. 3 is a block diagram of a memory cell 110 of an SRAM device employing memory cell segments 110-1-110-4 and write assist. The embodiments herein are not limited to any particular number of memory cell segments. Furthermore, the memory cells 105 are not shown in this illustration for the sake of clarity.

In this embodiment, the memory cell array 110 is configured with first and second metallization layers 111-1 and 111-2. The bitline pairs 130 and 140 each provide bit signals and their complements from global I/O to write to the memory cells 105 (e.g., bitline 130-1 provides a bit signal to write to a memory cell 105 and the bitline 130-2 provides a complement bit signal to the memory cell 105). Each of the bitline pairs 130 and 140 are configured in the same upper metallization layer 111-2 and the memory cells 105 of the memory cell segments 110-1-110-4 are configured in the lower metallization layer 111-1. The bitline pairs 130 and 140 couple to their associated memory cell segments 110-1-110-4 via local bitlines established in the memory cell segments 110-1-110-4. The local bitlines are not shown in this illustration for the sake of clarity but are shown and described in greater detail above in FIG. 2.

In this embodiment, the bitline pair 130 couples to the odd-numbered memory cell segments 110-1 and 110-3 whereas the bitline pair 140 couple to the even-numbered memory cell segments 110-2 and 110-4. The bitline pairs 130 and 140 run parallel to one another in the upper metallization layer 111-2. The write assist line 106 is run across the memory cell segments 110-1-110-4 in the upper metallization layer in “zig-zag” fashion proximate to bitline pairs 130 and 140 where they are coupled to their respective memory cell segments. For example, the write assist line 106 runs in between and generally parallel to the bitlines 130-1 and 130-2 where the bitlines 130-1 and 130-2 couple to local bitlines of the odd-numbered memory cell segments 110-1 and 110-3. The write assist line 106 zig-zags over to the bitline pair 140 at the memory cell segment boundaries 135 to run in between and generally parallel to the bitlines 140-1 and 140-2 where they are connected to the local bitlines of the even-numbered memory cell segments 110-2 and 110-4. This allows the coupling capacitance to be reduced in a manner similar to the embodiment discussed above.

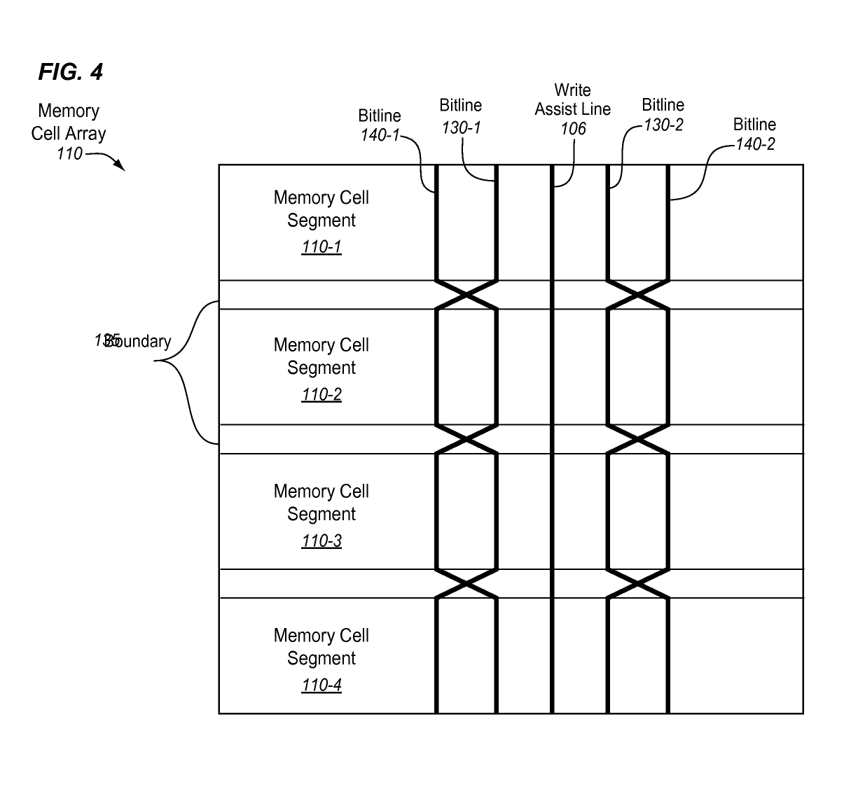

FIG. 4 is a block diagram of another segmented memory cell array 110 of an SRAM device 100 employing interleaved write assist. In this embodiment, the bitline pairs 130 and 140 and the write assist line 106 are again configured in the upper metallization layer 111-2. The memory cell array 110 is again segmented into memory cell segments 110-1-110-4 with the memory cells 105 being configured in the lower metallization layer 111-1. As with the embodiment in FIGS. 2 and 3, the memory cell segments 110-1-110-4 have local bitlines to which the global bitline pairs 130 and 140 couple. Differing from the embodiment in FIGS. 3 and 4 is the manner in which the individual bitlines are interleaved.

Again, the bitline pair 130 comprises the bitline 130-1 and its complement bitline 130-2 and the bitline pair 140 comprises the bitline 140-1 and its complement bitline 140-2. But, the bitlines 130-1 and 140-1 are interleaved with one another as are the complement bitlines 130-2 and 140-2. The write assist line 106 traverses the memory cell segments 110-1-110-4 through the upper metallization layer 111-2 in between the interleaved bitlines 130-1/140-1 and 130-2/140-2.

The bitline pair 130 again couples to the local bitlines of the odd memory cell segments 110-1 and 110-3 and the bitline pair 140 couples to the local bitlines of the even memory cell segments 110-2 and 110-4. The bitlines 130-1 and 140-1 “crisscross” at the memory segment boundaries 135. Thus, the bitlines 130-1 and 130-2 are closest in proximity to the write assist line 106 in the odd memory cell segments 110-1 and 110-3 and the bitlines 140-1 and 140-2 are closest in proximity to the write assist line 106 in the even memory cell segments 110-2 and 110-4. The couplings between the local bitlines of the memory cell segments and the global bitline pairs 130 and 140 are similar to that shown and described in FIG. 2.

This embodiment provides a similar reduction in coupling capacitance between the bitlines and the write assist line 106 described in the embodiment of FIG. 3. Thus, this embodiment provides a similar reduction in required power to the memory cell array 110.

It will be appreciated that the terms upper, lower, first, second, even, and odd and the like in the description are used for distinguishing between similar elements and not necessarily for describing a particular orientation or order. In other words, the terms so used are interchangeable under appropriate circumstances and the embodiments of the disclosure herein can operate in orientations and sequences other than that which is described or illustrated herein. Additionally, global bitlines and local bitlines could be placed in or configured with any conductive material such as metal or polysilicon.

What is claimed is:

1. A Static Random Access Memory device, comprising:
a plurality of memory cells;
a first metallization layer comprising a first pair of bitlines operable to couple to a first segment of the memory cells;
a second metallization layer comprising a second pair of bitlines operable to couple to a second segment of the memory cells; and
a write assist line interleaved with the first and second metallization layers to provide a substantially constant coupling capacitance with each of the first and second pairs of bitlines.

2. The Static Random Access Memory device of claim 1, wherein:
a first distance of the write assist line in the first metallization layer to one of the first pair of bitlines is substantially the same as a second distance of the write assist line in the second metallization layer to one of the second pair of bitlines.

3. The Static Random Access Memory device of claim 2, wherein:
the substantially same first and second distances are operable to provide the substantially constant coupling capacitance with each of the first and second pairs of bitlines.

4. The Static Random Access Memory device of claim 1, wherein:
the substantially constant coupling capacitance is operable to prevent a write assist signal through the write assist line from overdriving transistors in the memory cells.

5. The Static Random Access Memory device of claim 4, wherein:
the write assist signal provides a negative boost voltage based on a ratio of the substantially constant coupling capacitance to a capacitance of the bitlines.

6. The Static Random Access Memory device of claim 1, further comprising:
a global I/O module operable to transfer bit signals through the bitlines to write to the memory cells.

7. A Static Random Access Memory device, comprising:
a first metallization layer comprising first and second pairs of global bitlines;
a second metallization layer comprising first and second segments of memory cells, wherein each segment of memory cells comprises a pair of local bitlines coupled to the memory cells in the segment,
wherein the pair of local bitlines of the first segment is coupled to the first pair of global bitlines, and
wherein the pair of local bitlines of the second segment is coupled to the second pair of global bitlines; and
a write assist line interleaved with the first and second pairs of global bitlines based on couplings of the local bitlines to the global bitlines to provide a substantially constant coupling capacitance with each of the first and second pairs of bitlines.

8. The Static Random Access Memory device of claim 7, wherein:
the global bitlines of the first and second pairs of global bitlines are substantially parallel;
the write assist line traverses the first memory segment between the global bitlines of the first pair of global bitlines; and
the write assist line traverses the second memory segment between the global bitlines of the second pair of global bitlines.

9. The Static Random Access Memory device of claim 7, wherein:
a first distance of the write assist line to one of the first pair of bitlines is substantially the same as a second distance of the write assist line to one of the second pair of bitlines.

10. The Static Random Access Memory device of claim 9, wherein:
the substantially same first and second distances are operable to provide the substantially constant coupling capacitance with each of the first and second pairs of bitlines.

11. The Static Random Access Memory device of claim 7, wherein:
the substantially constant coupling capacitance is operable to prevent a write assist signal through the write assist line from overdriving transistors in the memory cells.

12. The Static Random Access Memory device of claim 11, wherein:
the write assist signal provides a negative boost voltage based on a ratio of the substantially constant coupling capacitance to a capacitance of the bitlines.

13. The Static Random Access Memory device of claim 7, further comprising:
a global I/O module operable to transfer bit signals through the bitlines to write to the memory cells.

14. A Static Random Access Memory device, comprising:
a first metallization layer comprising first and second pairs of global bitlines;
a second metallization layer comprising first and second segments of memory cells,
wherein each segment of memory cells comprises a pair of local bitlines coupled to the memory cells in the segment,
wherein the pair of local bitlines of the first segment is coupled to the first pair of global bitlines, and
wherein the pair of local bitlines of the second segment is coupled to the second pair of global bitlines; and
a write assist line that traverses the first and second segments of memory cells in the first metallization layer,
wherein a first global bitline of the first pair of global bitlines is interleaved with a first global bitline of the second pair of global bitlines, and
wherein the first global bitline of the first pair of global bitlines is closest in proximity to the write assist line in the first segment and the first global bitline of the second pair of global bitlines is closest in proximity to the write assist line in the second segment to provide a substantially constant coupling capacitance with each of the first and second pairs of bitlines across the first and second segments.

15. The Static Random Access Memory device of claim 14, wherein:
a first distance of the write assist line to the first global bitline in the first segment is substantially the same as a second distance of the write assist line to the second global bitline in the second segment.

16. The Static Random Access Memory device of claim 15, wherein:
the substantially same first and second distances are operable to provide the substantially constant coupling capacitance with each of the first and second pairs of bitlines.

17. The Static Random Access Memory device of claim 14, wherein:
the substantially constant coupling capacitance is operable to prevent a write assist signal through the write assist line from overdriving transistors in the memory cells.

18. The Static Random Access Memory device of claim 17, wherein:
the write assist signal provides a negative boost voltage based on a ratio of the substantially constant coupling capacitance to a capacitance of the bitlines.

19. The Static Random Access Memory device of claim 14, further comprising:
a global I/O module operable to transfer bit signals through the bitlines to write to the memory cells.
